(19) United States
(12) Patent Application Publication
(10) Pub. No.: US 2026/0252776 A1
(43) Pub. Date: Aug. 27, 2026

(54) METHOD OF GENERATING ASSIST PATTERNS

(71) Applicant: Samsung Electronics Co., Ltd., Suwon-si (KR)

(72) Inventors: Ingyun Chung, Suwon-si (KR); Minjae Kim, Suwon-si (KR)

(21) Appl. No.: 19/536,993

(22) Filed: Feb. 11, 2026

(30) Foreign Application Priority Data
Feb. 27, 2025 (KR) 10-2025-0026090

(51) Int. Cl. G06F 30/39

(52) U.S. Cl. CPC G06F 30/39

(57) ABSTRACT

An assist pattern generation method includes selecting a selective region in a mask, calculating an intensity map in the selective region, calculating an intensity function of an analysis region in the selective region, selecting locations of assist patterns and generating the assist patterns, recalculating the intensity function of the analysis region, comparing a first reference value to at least some of differences between first computed values of the intensity function, setting a residue threshold of the intensity function, comparing the residue threshold to at least some of the first computed values of the intensity function, and generating final assist patterns.

### CROSS-REFERENCE TO RELATED APPLICATION

This application claims priority under 35 U.S.C. § 119 to Korean Patent Application No. 10-2025-0026090, filed on Feb. 27, 2025, in the Korean Intellectual Property Office, the entirety of which is incorporated by reference herein.

### BACKGROUND

In semiconductor memory processes, microfabrication technology is rapidly advancing to increase the productivity of dynamic random-access memory (DRAM). In order to increase the number of chips that may be produced from a single wafer, it is required to reduce pitches of cells and metal wires to extremely small sizes and integrate layouts as compactly as possible. However, when the pitches are reduced significantly as described above, the patterning stability during exposure processes deteriorates considerably, and the possibility of defects occurring during actual production processes may increase. For example, while cell regions generally form regular patterns, cell edge regions (or unit block edge (UBE) regions) exhibit irregular patterns, and thus, it is difficult to secure sufficient depth of focus (DoF) by using optical proximity correction (OPC) alone. In particular, changes in line width or damage to patterns in the cell edge regions may directly affect product yield. Also, since metal wiring processes tend to use lighting conditions optimized for the minimum pitch, patterning margins may be reduced in patterns having relatively large pitches.

To solve these limitations, various attempts have been made to compensate for optical distortion of fine patterns. A typical method is to insert a sub-resolution assist feature (SRAF) or anti-SRAF according to certain rules to mitigate pattern distortion during an exposure process.

### SUMMARY

As the reduction in pitch has become increasingly extreme in recent DRAM processes, there are limitations to effectively coping with complicated pitch variations in cell edge regions and metal wiring regions by using simple rules alone. For example, as the difficulty of OPC increases, indicators such as the DoF and the uniformity of pattern line width deteriorate, which may adversely affect the product yield, reliability, and performance.

The Some aspects of the present disclosure provide methods of generating assist patterns, wherein a depth of focus is further secured by optimizing the assist patterns in a selective region, thereby securing a process margin.

The objects and advantages of the present disclosure are not limited to the foregoing, and others will be clearly understood by those skilled in the art from the following description.

According to some implementations of the present disclosure, there is provided an assist pattern generation method including selecting a selective region in a mask, calculating an intensity map in the selective region, calculating an intensity function of an analysis region in the selective region, selecting locations of assist patterns and generating the assist patterns, recalculating the intensity function of the analysis region, comparing a first reference value to at least some of differences between first computed values of the intensity function, setting a residue threshold of the intensity function, comparing the residue threshold to at least some of the first computed values of the intensity function, and generating final assist patterns.

According to some implementations of the present disclosure, there is provided an assist pattern generation method including selecting a selective region in a mask, calculating an intensity map in the selective region, calculating an intensity function of an analysis region in the selective region, selecting locations of assist patterns and generating the assist patterns, recalculating the intensity function of the analysis region, determining whether at least some of differences between first computed values of the intensity function are less than a first reference value, wherein the first computed values include values of local minima and inflection points of the intensity function, determining whether a difference between the first computed values of the intensity function and a residue threshold is greater than a second reference value, and generating final assist patterns, wherein, in the determining of whether at least some of the differences between the first computed values are less than the first reference value, when at least some of the differences between the first computed values are greater than the first reference value, sizes of the assist patterns are primarily adjusted, and in the determining of whether the difference between the first computed values and the residue threshold is greater than the second reference value, when the difference between the first computed values and the residue threshold is less than the second reference value, the sizes of the assist patterns are secondarily adjusted.

According to some implementations of the present disclosure, there is provided an assist pattern generation method including selecting a selective region in a mask, calculating an intensity map in the selective region, calculating an intensity function of an analysis region in the selective region, selecting locations of assist patterns and generating the assist patterns, recalculating the intensity function of the analysis region, determining whether at least some of differences between first computed values of the intensity function are less than a first reference value, wherein the first computed values include values of local minima and inflection points of the intensity function, determining whether a difference between the first computed values of the intensity function and a residue threshold is greater than a second reference value, and generating final assist patterns and manufacturing a mask including the final assist patterns, wherein, in the determining of whether at least some of the differences between the first computed values are less than the first reference value, when at least some of the differences between the first computed values are greater than the first reference value, sizes of the assist patterns are primarily adjusted, in the determining of whether the difference between the first computed values and the residue threshold is greater than the second reference value, when the difference between the first computed values and the residue threshold is less than the second reference value, the sizes of the assist patterns are secondarily adjusted, the intensity map in the selective region is calculated by rigorous simulation, and the rigorous simulation includes analyzing fine patterns based on Maxwell's equations, the calculating of the intensity function selectively includes performing noise filtering of the intensity map on the selective region, when the sizes of the assist patterns are primarily adjusted, the sizes of the assist patterns are adjusted so that at least some of the differences between the first computed values are less than the first reference value, when the sizes of the assist patterns are secondarily adjusted, if the difference between the first computed values and the residue threshold is less than the second reference value, the sizes of the assist patterns are adjusted so that a size of a transmissive assist pattern among the assist patterns decreases or a size of a block assist pattern among the assist patterns increases, and a range of depth of focus of the selective region including the final assist patterns generated in the generating of the final assist patterns is greater than a range of depth of focus of the selective region including the assist patterns generated in the generating of the assist patterns.

### BRIEF DESCRIPTION OF THE DRAWINGS

FIG. 1 is a flowchart showing an example of an assist pattern generation method;

FIGS. 2A to 2G are diagrams illustrating an example of an assist pattern generation method;

FIGS. 3A to 3E are diagrams illustrating an example of an assist pattern generation method;

FIGS. 4A to 4C are diagrams illustrating an example of an assist pattern generation method;

FIG. 5A is a diagram showing an example of a mask including assist patterns formed by general rules;

FIG. 5B is a diagram showing an example of a mask including assist patterns generated by an assist pattern generation method according to the present disclosure; and

FIGS. 6 to 8 are diagrams showing examples of masks including assist patterns generated and optimized by assist pattern generation methods according to the present disclosure.

### DETAILED DESCRIPTION

In the following, examples are provided to describe the concepts of the present disclosure. The following examples may be modified in many different forms without departing from the scope of this disclosure. In the drawings, the thickness and size of some elements may be exaggerated for convenience and clarity of illustration.

In some implementations, the present disclosure provides for “assist patterns” to be included in lithographic masks, e.g., photolithography masks. The assist patterns can be light-blocking patterns included in a region to be exposed during the lithography, e.g., a region of the mask that otherwise does not include a pattern to block light. The assist patterns can instead or additionally include transmissive mask patterns in a mask region that otherwise blocks light. In some implementations, the assist patterns can improve lithography quality in those regions.

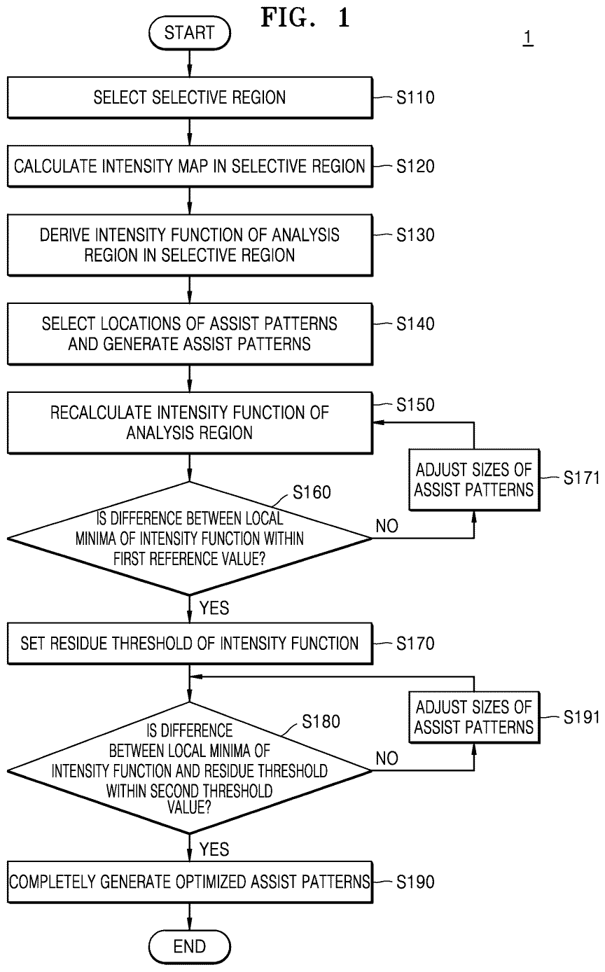

FIG. 1 is a flowchart showing an example of an assist pattern generation method 1.

Referring to FIG. 1, the assist pattern generation method 1 may include operation S110 of selecting a selective region. The selective region may include, for example, a region including isolated polygons and spaces in cell edge regions and metal wires in a mask. By comparing a plurality of zones of the mask to each other, zones with the highest degree of isolation or zones separated from repetitive patterns may be selected as priorities. The degree of isolation may be determined by evaluating patterns that lack regularity or the sizes of patterns relative to fine patterns that repeat in cell regions. Also, the degree of isolation may be determined based on the possibility of relatively deviating from the range of depth of focus when performing an exposure process on the fine pattern.

The assist pattern generation method 1 may include operation S120 of calculating an intensity map in the selective region. The intensity map in the selective region selected in operation S110 of selecting the selective region may be calculated. The intensity map may be obtained by computing the intensity of light exposure during the exposure process of a mask with respect to a region of interest. For example, the intensity map can represent an intensity of light transmitted (exposed) through the mask. Operation S120 of calculating the intensity map may be performed while no assist pattern is generated in the selective region.

In operation S120 of calculating the intensity map in the selective region, the intensity map of light reaching a wafer to be processed in the selective region may be calculated by using a rigorous simulation. As used herein, the rigorous simulation may refer to a physics-based electromagnetic simulation. The rigorous simulation may be used to model and comprehend various electromagnetic phenomena, including light propagation, diffraction, and pulse transmission.

In some implementations, the rigorous simulation may not incorporate optical factors, including the numerical aperture intensity log slope (NILS), the mask error enhancement factor (MEEF), the depth of focus (DoF), and the point of variation band (PV Band). In some implementations, the rigorous simulation incorporates optical phenomena occurring in the fine pattern are precisely analyzed based on Maxwell's equations. The rigorous simulation may include a rigorous coupled-wave analysis (RCWA) technique, a finite-difference time-domain (FDTD) technique, and/or a waveguide analysis technique.

The rigorous simulation may include a process of computing the actual distribution of intensity reaching the wafer by analyzing the propagation, diffraction, scattering, and interference of electromagnetic waves with respect to a three-dimensional structure of fine patterns. The rigorous simulation may include a process of analytically or numerically solving Maxwell's equations when analyzing the electromagnetic waves.

When the rigorous simulation is applied to a region of the mask above a certain level (e.g., above a certain size), this may be computationally intensive. In some implementations of the assist pattern generation method 1, the rigorous simulation is performed only for the selective region that has been selected, and thus, calculation resources are not excessively consumed.

The assist pattern generation method 1 may include operation S130 of computing an intensity function of an analysis region in the intensity map. The analysis region may be set linearly for part of the selective region (e.g., may be set as a line shape) or set for a certain region in the mask. The analysis region may be part of the selective region. The intensity function may be computed for parts of the intensity map corresponding to the analysis region. The analysis region may also be referred to as a gauge.

In some implementations, operation S130 of computing the intensity function of the analysis region in the intensity map may further include performing noise filtering of the intensity map on the selective region. For example, when the analysis region is set as a certain region (e.g., when the analysis region is set as a two-dimensional region) assist pattern generation method 1 may include an operation of performing noise filtering of the intensity map on the selective region. Not only when the analysis region is set for a certain region, but also, in some implementations, when the analysis region is set for a one-dimensional linear region, the assist pattern generation method 1 may include an operation of performing noise filtering of the intensity map on the selective region.

The noise filtering may be performed for the purpose of subsequently performing operation S130 of computing the intensity function. When the analysis region is set as a certain region, for example, the intensity map may become discontinuous or the intensity values may change dramatically due to noise. The noise filtering may be performed to remove the noise and compute the intensity function of the analysis region.

The noise filtering may include, for example, polynomial regression fitting. The polynomial regression fitting may represent a method of calculating an approximation function with a polynomial for the measured data, modeling a curved surface or a curved line, and ignoring small fluctuations (noise) in the actual measured data while retaining the essential data. However, the noise filtering in the assist pattern generation method 1 is not limited to the polynomial regression fitting.

The assist pattern generation method 1 may include operation S140 of selecting the location of the assist pattern and generating the assist pattern from the intensity function. The location of the assist pattern may be selected based on the intensity function. In some implementations, the locations of the assist patterns may be selected as at least some of the locations at which local extrema and inflection points of the intensity function appear.

In some implementations, the locations of the assist patterns may be selected as at least some of the locations other than the local maxima among the local extrema and inflection points of the intensity function. Also, in some implementations, the locations of the assist patterns may be selected as all of the locations other than the local maxima among the local extrema and inflection points of the intensity function.

After the location of the assist pattern is selected, the assist pattern may be generated. For example, the assist pattern may be generated in the smallest width as an assist pattern. In some implementations, the sizes of the assist patterns may be selected by considering (e.g., based on) the sizes of the patterns and spaces in the selective region and the number of assist patterns to be generated. In some implementations, the assist pattern may be generated so as to have a width similar to that of the pattern having the smallest line width among the patterns of the cell region of the mask. In some implementations, the smallest assist pattern may be generated based on mask rule check (MRC). For example, the assist pattern may be a smallest assist pattern that satisfies the MRC. The MRC inspects whether the mask pattern exceeds process limits and may verify that the designed mask pattern complies with factors, such as minimum line width, spacing, and resolution limits.

The assist pattern generation method 1 may include operation S150 of recalculating the intensity function of the analysis region. Since one or more assist patterns have been generated in the analysis region, the intensity map may be generated from the assist patterns through the rigorous simulation, and the intensity function of the analysis region may be computed from the intensity map. Operation S150 of recalculating the intensity function of the analysis region may include reperforming the process of calculating the intensity map and computing the intensity function described above, e.g., now based on the presence of the generated assist patterns. The recalculating of the intensity function described herein may include reperforming the process of calculating the intensity map and computing the intensity function. The intensity function after recalculating may still be referred to as “the intensity function,” though its values may be changed from before recalculation.

The assist pattern generation method 1 may include operation S160 of determining whether the difference between the local minima of the intensity function is within a first reference value or otherwise satisfies a first threshold condition. In some implementations, the difference between the local minima of the intensity function may be compared to the first reference value.

In operation S160 of determining whether the difference between the local minima is within the first reference value, one or more local minima of the intensity function may exist. When the intensity function has two or more local minima, the process of comparing the difference between the local minima may include the process of comparing two or more local minima having substantially similar values. For example, the process above may include comparing differences between local minima with relatively small differences, rather than comparing differences between local minima with relatively large differences. Also, for example, it may be determined whether the difference between adjacent local minima is within the first reference value.

The first reference value may be set as a ratio relative to the maximum intensity value or as the magnitude of the intensity value. For example, the first reference value may be set as a value within a range of about 1% to about 5% of the maximum intensity value. In some implementations, the first reference value may be set as a value within a range of about 0.1 to about 0.5 based on normalized values. In some implementations, the first reference value may be set within a range of about 0.1 mJ/cm² to about 1 mJ/cm². The range and unit of the first reference value may vary depending on a user's settings, and thus, the scope of the present disclosure is not limited to a particular range of first reference values.

Operation S160 of determining whether the difference between the local minima is within the first reference value may be repeated when the condition described above is not satisfied, and operation S171 of adjusting the size of the assist pattern may be repeated one or more times.

The assist pattern generation method 1 may include operation S170 of setting a residue threshold of the intensity function. In operation S160 of determining whether the difference between the local minima is within the first reference value, when the difference between the local minima of the intensity function is within the first reference value, operation S170 of setting the residue threshold of the intensity function may be performed. The residue threshold may be referred to as a residual intensity limit. The residue threshold of the intensity function may include a value that is calculated and set or a value that is preset.

The residue threshold may represent a threshold intensity value corresponding to a level at which a pattern is formed by the assist pattern in the mask during the exposure process. That is, the residue threshold represents the threshold intensity value that is based on the assist pattern formed on the mask during the exposure process and determines whether an actual pattern is formed on the wafer. That is, when the intensity near the assist pattern falls below the residue threshold, unwanted assist patterns may be formed as residue on the wafer. In order to prevent the formation of unwanted patterns, it may be advantageous to design and adjust the exposure conditions so that the intensity in an assist pattern region is maintained above the residue threshold. For example, the assist pattern may be configured to reduce an exposure intensity of light in a region in which the assist pattern is arranged, without reducing the exposure intensity so much that results in an actual pattern being formed corresponding to the assist pattern.

The assist pattern generation method 1 may be described based on a negative tone development (NTD) method. In the NTD process, generally, exposed regions remain after development, and unexposed regions may be removed. Due to these process characteristics, the residue threshold may be used as a criterion for determining the possibility that the assist pattern remains as the actual pattern when the exposure intensity falls below a certain reference value. However, the lithography type is not limited to the NTD process described above, and the same or similar principles may apply to positive tone development (PTD). That is, the scope of this disclosure is not limited to the NTD process.

When the intensity of the assist pattern decreases based on the residue threshold described below, there is a possibility that the assist pattern remains as an actual pattern. This is due to the characteristics that, for example, during the NTD process, the exposed regions remain and the unexposed regions are removed. On the other hand, in the PTD process, the size of assist patterns may be adjusted based on the local maxima and the inflection points, which is different from the assist pattern generation method in the NTD process in which the size of assist patterns is adjusted based on the local minima and the inflection points.

Operation S170 of setting the residue threshold of the intensity function may be performed after or before operation S160 of determining whether the difference between the local minima is within the first reference value. For example, a specific value may be input by a user for a residue limit of the intensity function. Before operation S180 of determining whether the difference between the local minimum of the intensity function and the residue threshold is greater than a second reference value, which is described below, the residue limit of the intensity function may be input. For example, the residue limit of the intensity function may be input in operation S110 of selecting the selective region, operation S120 of calculating the intensity map in the selective region, or the like.

The assist pattern generation method 1 may include operation S171 of adjusting the size of the assist pattern. In operation S160 of determining whether the difference between the local minima of the intensity function is within the first reference value, when the difference between the local minima of the intensity function deviates from the first reference value, operation S171 of adjusting the size of the assist pattern may be performed. The sizes of one or more assist patterns may be adjusted by increasing or decreasing the sizes of the assist patterns. The assist pattern after size adjustment may still be referred to as “the assist pattern,” though a size of the assist pattern may be different from before adjustment.

For example, when the assist pattern is generated with the size set to the minimum, the size of the assist pattern may be adjusted by increasing the size of the assist pattern in operation S171 of adjusting the size of the assist pattern so that the difference between the local minima of the intensity function is adjusted to be within the first reference value.

After operation S171 of adjusting the size of the assist pattern is performed, operation S150 of recalculating the intensity function of the analysis region may be performed. When the size of the assist pattern changes, the intensity function of the analysis region changes accordingly. Therefore, the intensity map of the selective region is calculated again by the rigorous simulation, and the process of computing the intensity function of the analysis region may be performed again.

The assist pattern generation method 1 may include operation S180 of determining whether the difference between the local minimum of the intensity function and the residue threshold is greater than the second reference value or otherwise satisfies a second threshold condition. The difference between the residue threshold and one or more local minima computed in operation S160 of determining whether the difference between the local minima is within the first reference value is computed, and the computed value is compared to the second reference value.

In some implementations, the differences between at least one local minimum of the intensity function and the residue threshold may each be calculated. Subsequently, when the difference between the local minimum and the residue threshold is greater than the second reference value, the next operation may be performed. When the difference between the local minimum and the residue threshold is less than or equal to the second reference value, there is a possibility that residue is generated due to the assist pattern. Therefore, operation S191 of adjusting the size of the assist pattern may be performed.

Also, in some implementations, an operation of directly comparing the local minimum of the intensity function to the residue threshold may replace operation S180 of determining whether the difference between the local minimum of the intensity function and the residue threshold is greater than the second reference value. For example, when the local minimum of the intensity function is greater than the residue threshold, next operation S190 may be performed. Also, when the local minimum of the intensity function is less than or equal to the residue threshold, operation S191 of adjusting the size of the assist pattern may be performed.

Also, in some implementations, in operation S180 of determining whether the difference between the local minimum of the intensity function and the residue threshold is greater than the second reference value, when the difference between the local minimum and the residue threshold is less than or equal to the second reference value, operation S171 of adjusting the size of the assist pattern may be performed, and operation S150 of recalculating the intensity function may be performed.

The second reference value may be set as a ratio relative to the maximum intensity value or as the magnitude of the intensity value. For example, the second reference value may be set as a value within a range of about 1% to about 5% of the maximum intensity value. As another example, the second reference value may be set as a value within a range of about 0.1 to about 0.5 based on normalized values. As another example, the second reference value may be set within a range of about 0.1 mJ/cm² to about 1 mJ/cm². The range of the second reference value may vary depending on a user's settings, and thus, the ranges of the second reference values are not limited to the foregoing ranges.

Operation S180 of determining whether the difference between the local minimum of the intensity function and the residue threshold is greater than the second reference value may be repeated when the condition described above is not satisfied, and operation S191 of adjusting the size of the assist pattern may be repeated one or more times.

The assist pattern generation method 1 may include operation S191 of adjusting the size of the assist pattern. The size of the generated assist patterns may be adjusted so that the difference between the local minimum of the intensity function and the residue threshold is greater than the second reference value. For example, when a small assist pattern is generated based on the MRC, the size of the assist pattern may be adjusted by increasing the size of the assist pattern.

The assist pattern generation method 1 may include operation S190 of completely generating a final or optimized assist pattern through the processes described above. After the assist pattern has been optimized, the range of DoF of the selective region including the optimized assist pattern may be greater than the range of DoF of the selective region including the assist pattern in operation S140 of generating the assist pattern. The mask including the optimized final assist pattern may be manufactured. The final assist pattern can be referred to as being generated based on adjusted sizes of assist patterns through operations S171 and/or S191, even if the adjusted sizes have been further iterated, because the final assist pattern arises through the adjusted sizes.

Hereinafter, the assist pattern generation method 1 is described in more detail.

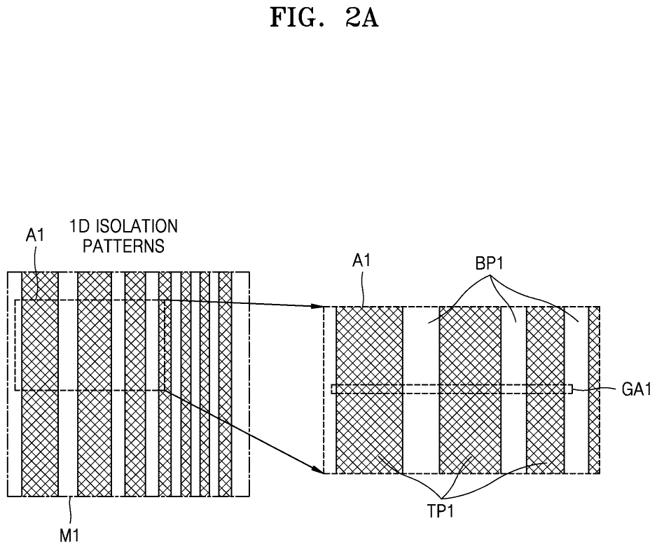

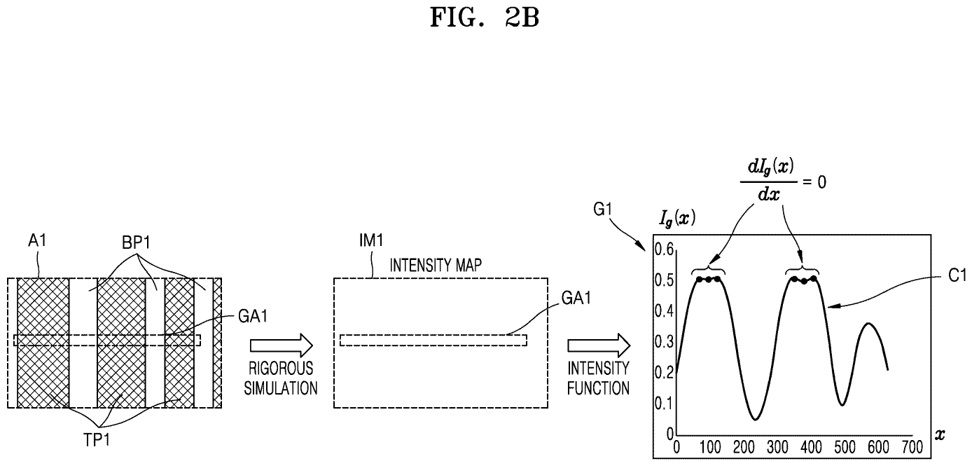

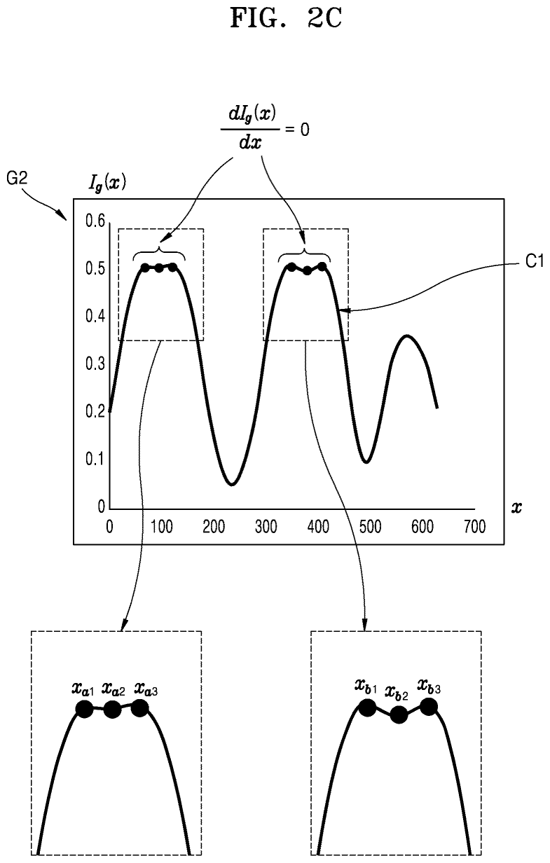

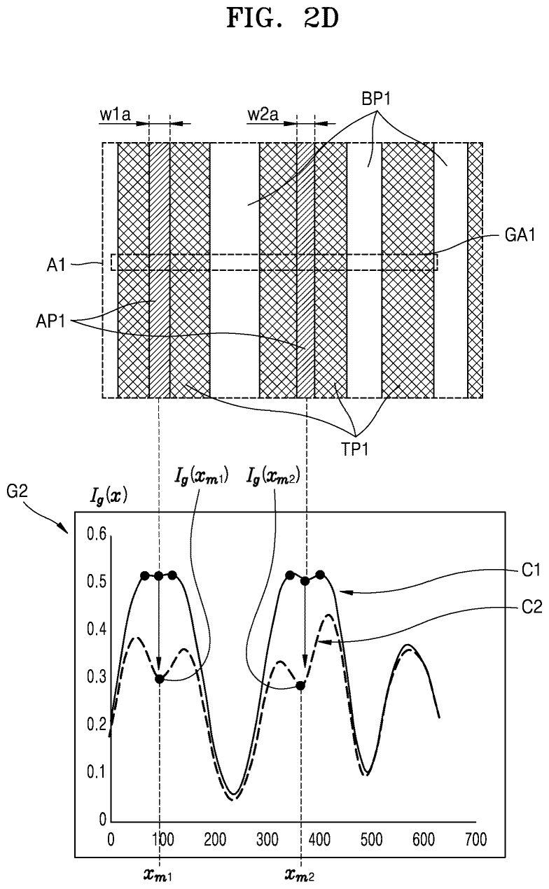

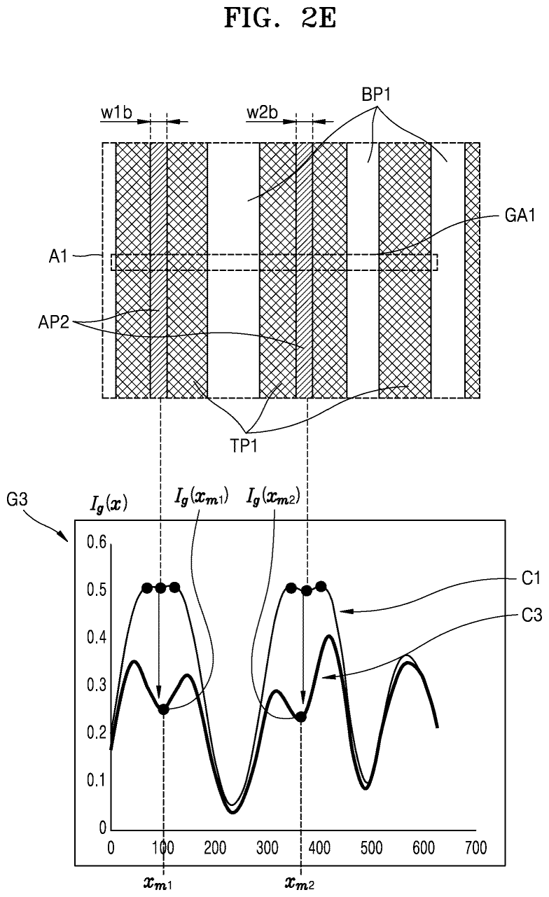

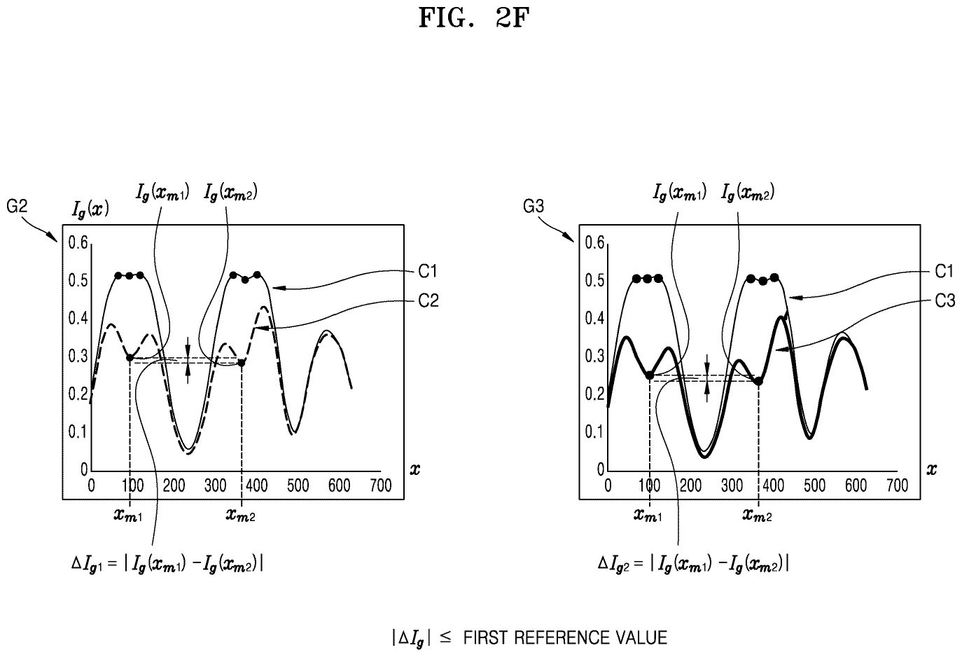

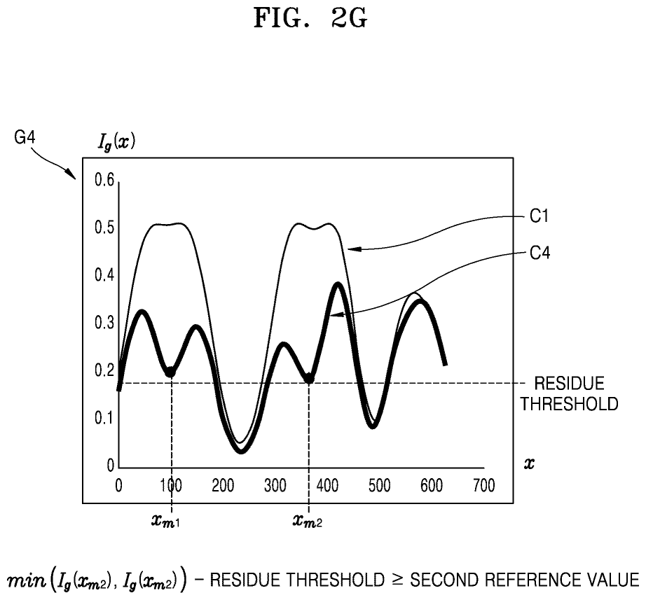

FIGS. 2A to 2G are diagrams illustrating the assist pattern generation method 1. Those components not described below may be substantially the same as the above. More specifically, FIGS. 2A to 2G are diagrams illustrating an example in which the assist pattern generation method 1 is applied to a one-dimensional (1D) isolation pattern.

Referring to FIG. 2A, a first selective region A1 including a 1D isolation pattern may be selected from a first mask M1. That is, operation S110 of selecting the selective region may be performed. The first selective region A1 may be included in the selective region described above with reference to FIG. 1. A mask pattern provided in the first selective region A1 may be provided linearly. For example, the first selective region A1 may represent a pattern that is relatively spaced apart from repetitive patterns of the first mask M1.

The 1D isolation pattern may represent an isolated line or space structure that extends in a specific direction on the plan layout of the mask and has no identical or similar patterns nearby. For example, the 1D isolation pattern represents a pattern (or a space) that is formed lengthwise in the first direction and has few or no patterns adjacent thereto or is far away from adjacent patterns in a second direction perpendicular to the first direction. The 1D isolation pattern may represent a pattern around which there are no patterns in other directions (e.g., in directions besides the extension direction of the pattern), or around which there are no other shapes that may interfere with or diffractively interact with the pattern.

For example, the 1D isolation pattern may include a space in which only a single wire is placed on a metal layer of the mask or a space in which no further patterns are present at the outermost periphery of the cell region.

Part of the first selective region A1 may be selected as a first analysis region GA1. The first analysis region GA1 may be included in the selective region described above with reference to FIG. 1. The first analysis region GA1 may represent a region in which intensity is measured and evaluated more intensively. The first analysis region GA1 may be selected as part of the region that is representative of the 1D isolation pattern of the first selective region A1.

In the first selective region A1, darker regions may represent first transmissive patterns TP1, and lighter regions may represent first block patterns BP1. The pattern on the wafer, corresponding to the first block pattern BP1, may include, for example, a wiring pattern.

The 1D isolation pattern may have no identical or similar patterns adjacent thereto, thereby minimizing optical effects such as optical multiple interference and diffraction. At the same time, this pattern may be relatively susceptible to process defects, such as pattern discontinuity and critical dimension (CD) deviation. Therefore, when the assist pattern according to the intensity with respect to the 1D isolation pattern is inserted into the 1D isolation pattern by the assist pattern generation method 1, the DoF of the 1D isolation pattern may be further secured, thereby improving yields in semiconductor manufacturing.

Referring to FIG. 2B, an intensity map IM1 for the first selective region A1 may be calculated. That is, operation S120 of calculating the intensity map in the selective region may be performed. The intensity map IM1 may be calculated for the first selective region A1 by the rigorous simulation described above. In some implementations, after the intensity map IM1 for the first analysis region GA1 of the 1D isolation pattern is calculated, noise filtering may be performed. The noise filtering may include, for example, polynomial regression fitting.

For the intensity map IM1, the intensity function for the first analysis region GA1 may be computed. A first intensity function C1 representing an intensity function I_{g} (x) for the first analysis region GA1 may be computed as shown in a first graph G1. That is, operation S130 of computing the intensity function of the analysis region in the intensity map may be performed.

For the first intensity function C1, the process of obtaining the local extrema corresponding to

$$\frac{{dI}_{g} ( x )}{d x} = 0$$

may be performed. For example, as shown in the first intensity function C1 of the first graph G1 in FIG. 2B, a total of six local extrema may be computed. The local extrema may include local minima and local maxima.

Referring to FIG. 2C, operation S140 of selecting the location of the assist pattern and generating the assist pattern from the intensity function may be performed. The location of the assist pattern may be selected based on the intensity function. In some implementations, the locations of the assist patterns may be selected as at least some of the locations at which local extrema and inflection points of the intensity function appear.

In the first graph G1, for example, six local extrema of the first intensity function C1 may be computed. xₐ₁, xₐ₃, x_{b1}, and x_{b3} may be calculated as local maxima, and xₐ₂ and x_{b2} may be calculated as local minima. For example, the assist patterns may be generated at locations corresponding to xₐ₂ and x_{b2}.

Referring to FIG. 2D, a first assist pattern AP1 may be provided at each of the locations corresponding to xₐ₂ and x_{b2} of the first transmissive patterns TP1, as shown in the upper diagram of FIG. 2D. The first assist pattern AP1 is inserted as an assist pattern of a first transmissive pattern TP1 through which light is transmitted, and the first assist pattern AP1 may be a type of block pattern. The first assist pattern AP1 may be set, for example, at its minimum size. For example, the pattern described above may correspond to the smallest assist pattern based on the MRC. The two line assist patterns corresponding to the first assist pattern AP1 may respectively have widths w₁ₐ and w₂ₐ. The widths of the two line assist patterns may be equal to or different from each other.

For example, as the width of the first transmissive pattern TP1 in which each of the two line assist patterns is located increases, the width of the corresponding line assist pattern may increase. For example, when the width of the left transmissive pattern among the first transmissive patterns TP1 of the first selective region A1 is greater than the width of the central transmissive pattern among the first transmissive patterns TP1 of the first selective region A1, the width w₁ₐ of the line assist pattern located on the left transmissive pattern among the first transmissive patterns TP1 of the first selective region A1 may be greater than the width w₂ₐ of the line assist pattern located on the central transmissive pattern among the first transmissive patterns TP1 of the first selective region A1. The feature described above may be adjusted according to the width of the transmissive pattern in which the assist pattern is located. For example, wider transmissive regions may be provided with wider assist patterns.

After the first assist pattern AP1 is inserted, operation S150 of recalculating the intensity function of the analysis region may be performed. A second intensity function C2 that is different from the first intensity function C1 may be computed. After the first assist pattern AP1 is inserted, the intensity map for the first selective region A1 may be recalculated by the rigorous simulation, and similarly, the second intensity function C2, which represents an intensity function for the first analysis region GA1, may be computed.

As shown in a second graph G2 in which the first intensity function C1 and the second intensity function C2 are shown together, the intensity values at xₘ₁ and xₘ₂ corresponding to xₐ₂ and x_{b2}, respectively, which correspond to local minima in the first intensity function C1, may be lowered. That is, the value of I_{g} (xₘ₁) is less than the value of I_{g} (xₐ₂), and the value of I_{g} (xₘ₂) is less than the value of I_{g} (x_{b2}). This is because the first assist pattern AP1 is inserted at each of the locations corresponding to xₐ₂ and x_{b2}, thereby blocking the emitted light.

Referring to FIG. 2E, a second assist pattern AP2 that is different from the first assist pattern AP1 of FIG. 2D may be generated and located in the first selective region A1. As shown in the upper diagram of FIG. 2E, the second assist pattern AP2 may be provided at each of the locations corresponding to xₐ₂ and x_{b2} of the first transmissive pattern TP1. The two line assist patterns corresponding to the second assist pattern AP2 may respectively have widths w_{1b} and w_{2b}. The widths of the two line assist patterns may be equal to or different from each other.

The width w₁ₐ of the assist pattern corresponding to the left side among the first assist patterns AP1 in FIG. 2D may be different from the width w_{1b} of the assist pattern corresponding to the left side among the first assist patterns AP1 in FIG. 2E. Similarly, the width w₂ₐ of the assist pattern located at the center among the first assist patterns AP1 in FIG. 2D may be different from the width w_{2b} of the assist pattern corresponding to the center among the first assist patterns AP1 in FIG. 2E.

After the second assist pattern AP2 is inserted, operation S150 of recalculating the intensity function of the analysis region may be performed. A third intensity function C3 that is different from both the first intensity function C1 and the second intensity function C2 may be computed.

As shown in a third graph G3 in which the first intensity function C1 and the third intensity function C3 are shown together, the intensity values at xₘ₁ and xₘ₂ corresponding to xₐ₂ and x_{b2}, respectively, which correspond to local minima in the first intensity function C1, may be lowered. That is, I_{g} (xₘ₁) is less than I_{g} (xₐ₂), and I_{g} (xₘ₂) is less than I_{g} (x_{b2}). The comparison between the second intensity function C2 and the third intensity function C3 is described below.

Referring to FIG. 2F, the second graph G2 and the third graph G3 are shown together. Operation S160 of determining whether the difference between the local minima of the intensity function is within the first reference value may be performed. For example, the difference between the local minima of the second intensity function C2 may not be within the first reference value.

The absolute value of the difference between the values of I_{g} (xₘ₁) and I_{g} (xₘ₂) of the second intensity function C2, i.e., ΔI_{g1}, which represents the magnitude of the difference between the values of I_{g} (xₘ₁) and I_{g} (xₘ₂) of the second intensity function C2, may be computed. When ΔI_{g1}, which represents the difference between the local minima of the second intensity function C2, exceeds the first reference value, for example, operation S171 of adjusting the size of the assist pattern may be performed so that the size of the first assist pattern AP1 inserted in the second intensity function C2 is adjusted. Subsequently, operation S150 of recalculating the intensity function of the analysis region may be performed so that the intensity function is calculated again.

In some implementations, when the difference between the local minima of the intensity function is greater than or equal to the first reference value, the size of the assist pattern may be adjusted and the intensity function may be calculated again.

The first assist pattern AP1 may be adjusted to increase in size, and then the second assist pattern AP2 may be located within the first selective region A1. Subsequently, the intensity function may be calculated, and the third intensity function C3 may be computed. For example, when each size of the second assist patterns AP2 is greater than each size of the first assist patterns AP1, the values of I_{g} (xₘ₁) and I_{g} (xₘ₂), which represent the local minima of the third intensity function C3, may be less than those of I_{g} (xₘ₁) and I_{g} (xₘ₂), which represent the local minima of the second intensity function C2, respectively.

For example, I_{g} (xₘ₁) of the second intensity function C2 may be greater than I_{g} (xₘ₂). When I_{g} (xₘ₁) of the second intensity function C2 is greater than I_{g} (xₘ₂), the increase in the size of the first assist pattern AP1 located at xₘ₂ may be greater than the increase in the size of the first assist pattern AP1 located at xₘ₁ during adjustment of the size of the first assist pattern AP1. For example, the value of w_{2b}-w₂ₐ may be greater than that of w_{1b}-w₁ₐ.

As the size of the assist pattern is adjusted in such a manner, ΔI_{g1} may be changed to ΔI_{g2}, and the ΔI_{g2} representing the difference between the values of I_{g} (xₘ₁) and I_{g} (xₘ₂) of the third intensity function C3 may be less than the first reference value.

This is only an explanation to help understand the adjustment of the size of the assist pattern and the reduction of the difference in local minima. A person skilled in the art will understand that the change in the intensity function value depending on the size of the assist pattern may be different from the above explanation due to various factors.

As described above, when the local minima of the intensity function have more uniform values by adjusting the difference between the local minima of the intensity function to be below the first reference value, the deviation of the CD in the actual exposure result on the wafer tends to decrease, and the DoF range also tends to increase. The assist pattern generation method 1 may maximize the process margin of the DoF through the process of reducing the difference between local minima of the intensity function, thereby reducing defects in fine patterns and improving yield.

As described above, the first reference value may be set as a ratio relative to the maximum intensity value or as the magnitude of the intensity value. For example, the first reference value may be set as a value within a range of about 1% to about 5% of the maximum intensity value. As another example, the first reference value may be set as a value within a range of about 0.1 to about 0.5 based on normalized values. As another example, the first reference value may be set within a range of about 0.1 mJ/cm² to about 1 mJ/cm². The range of the first reference value may vary depending on a user's settings, and thus, the ranges of the first reference value are not limited to the foregoing.

Referring to FIG. 2G, after operation S170 of setting the residue threshold of the intensity function, operation S180 of determining whether the difference between the local minimum of the intensity function and the residue threshold is greater than the second reference value may be performed. This may be performed by determining whether the difference between the residue threshold and the smallest of the local minima of a fourth intensity function C4 is greater than the second reference value.

For example, among the local minima I_{g} (xₘ₁) and I_{g} (xₘ₂) of the fourth intensity function C4 shown in a fourth graph G4, the smaller value I_{g} (xₘ₂) is greater than or equal to the residue threshold as shown in the fourth graph G4, and the difference between I_{g} (xₘ₂) and the residue threshold is greater than or equal to the second reference value, and thus, the assist pattern may be completely generated.

When the local minima I_{g} (xₘ₁) and I_{g} (xₘ₂) of the fourth intensity function C4 shown in the fourth graph G4 are greater than or equal to the residue threshold as shown in the fourth graph G4, and all of the local minima of the fourth intensity function C4 are greater than the residue threshold by at least the second reference value, the assist pattern may be completely generated. The fourth intensity function C4 shown in the fourth graph G4 may represent the intensity function obtained after operation S160 of determining whether the difference between the local minima of the intensity functions is within the first reference value.

For example, when all of the local minima of the fourth intensity function C4 are greater than the residue threshold, and the smallest value among the differences between the individual local minima of the fourth intensity function C4 and the residue threshold is greater than or equal to the second reference value, the assist pattern may be completely generated. When both the local minima I_{g} (xₘ₁) and I_{g} (xₘ₂) of the fourth intensity function C4 are greater than the residue threshold, and the smallest value among the difference between the local minima I_{g} (xₘ₁) of the fourth intensity function C4 and the residue threshold and the difference between the local minima I_{g} (xₘ₂) of the fourth intensity function C4 and the residue threshold, i.e., “I_{g} (xₘ₂)—residue threshold,” is greater than or equal to the second reference value, the assist pattern may be completely generated.

The assist pattern generation method 1 may secure a margin corresponding to the second reference value with respect to the residue threshold (e.g., may provide an intensity function that is at least the second reference value above the residue threshold), thereby preventing the assist pattern from actually being patterned as residue. Therefore, the assist pattern generation method 1 may optimize the generation of assist patterns.

The assist pattern generation method 1 may optimize the locations and sizes of assist patterns through the intensity function in the selective region, such as the 1D isolation pattern, thereby securing process margins, such as DoF. The residue threshold is adopted to prevent the assist pattern from forming as residue on the wafer.

As the deviation between the local minima of the intensity is reduced (e.g., through the process described above), the uniformity of fine patterns may be improved and the process margin of the DoF may be secured.

Also, the assist pattern generation method 1 may repeatedly calculate and adjust only the intensity without considering complicated optical parameters, thereby efficiently reducing the calculation load and time required in the mask generating process.

In addition, the assist pattern generation method 1 may not only be applied to the 1D isolation pattern described above, but also applied in the same manner to a two-dimensional (2D) isolation pattern of a cell edge region or a metal wiring layer as described below and may thus be widely used throughout microfabrication processes.

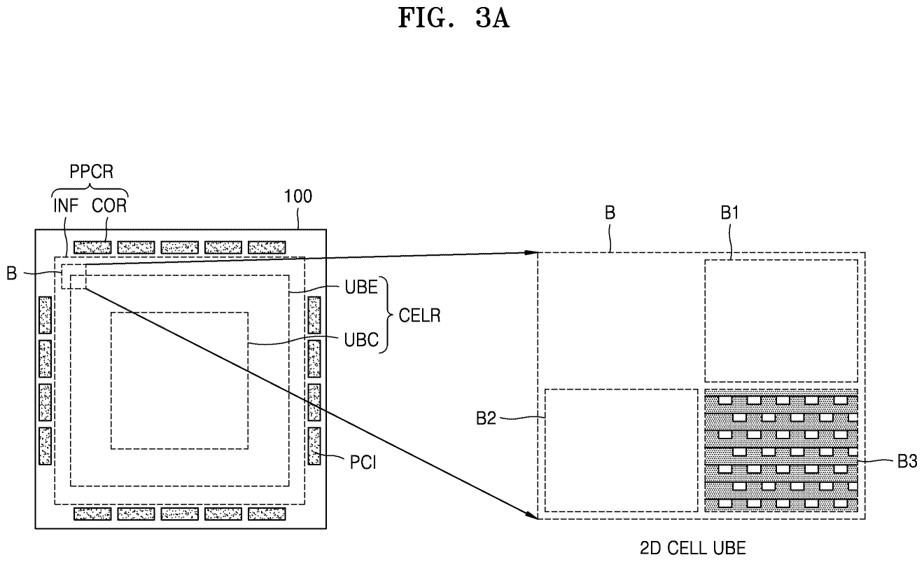

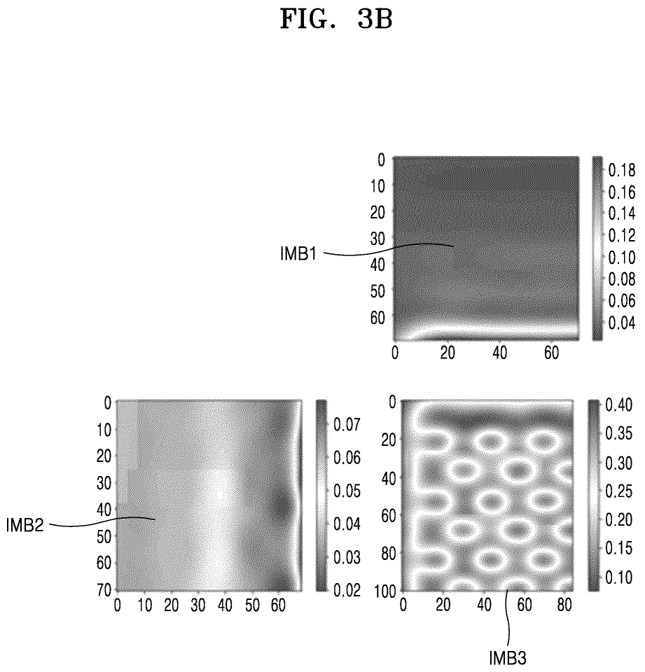

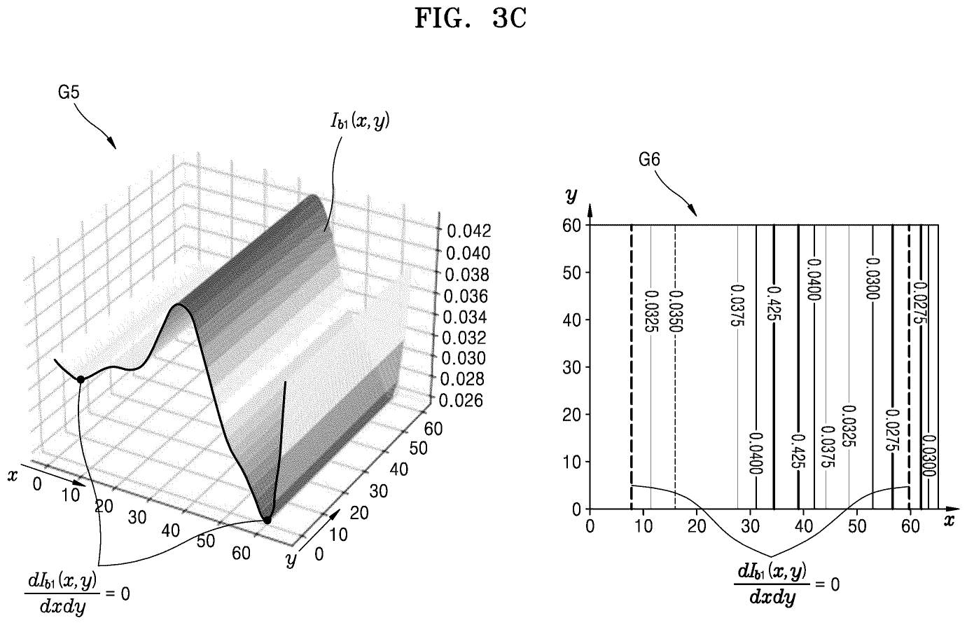

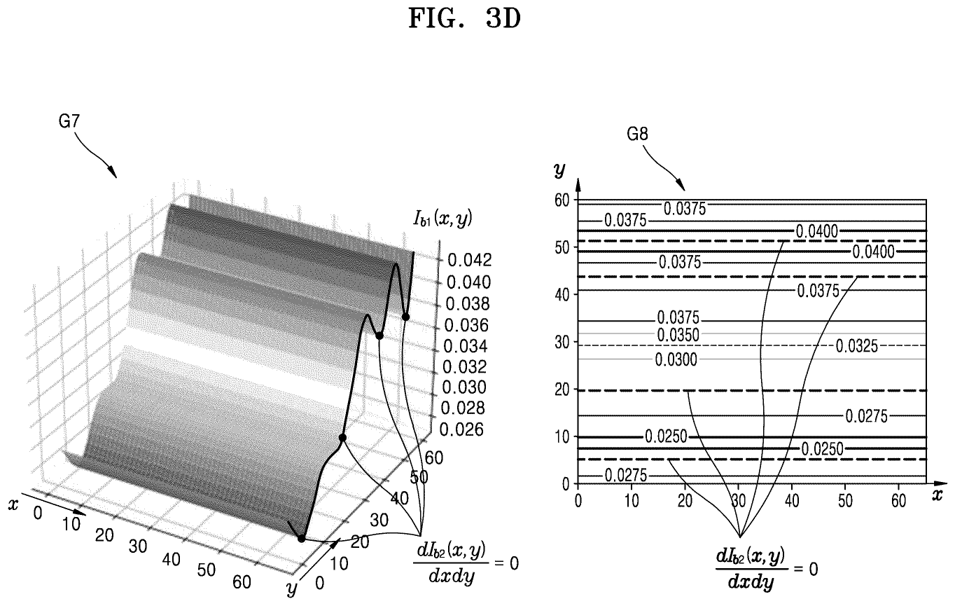

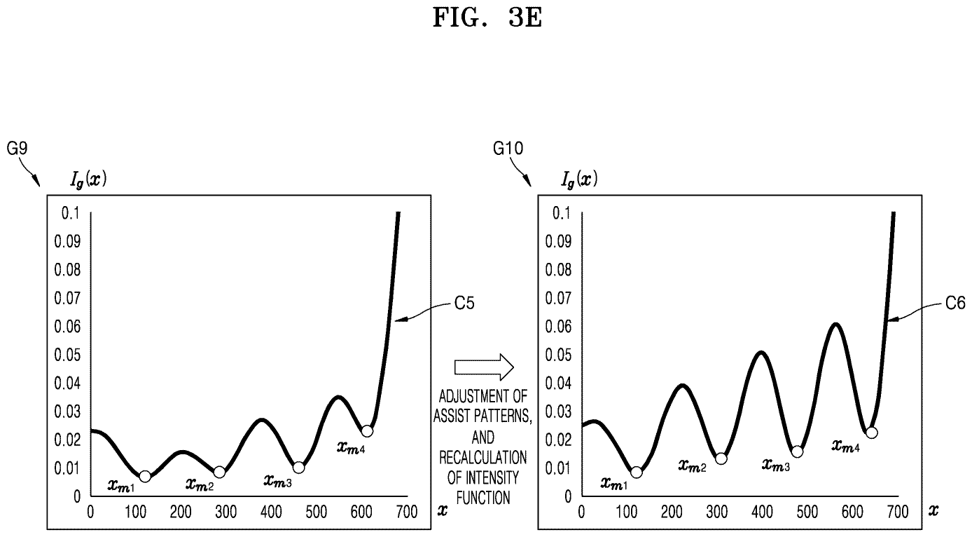

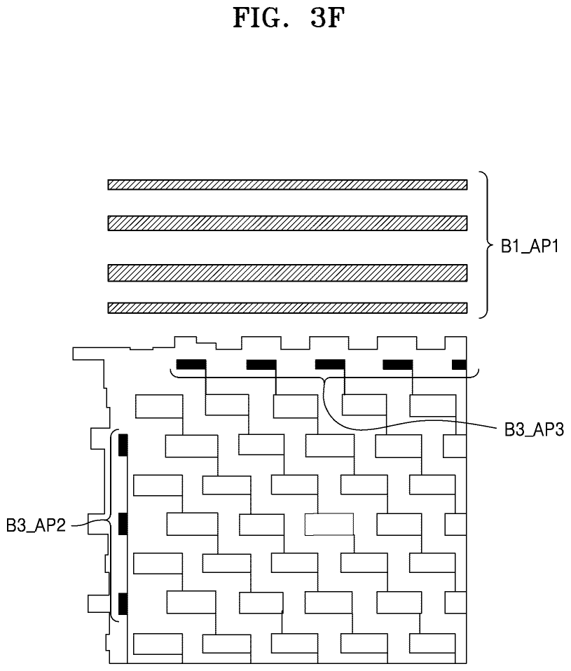

FIGS. 3A to 3E are diagrams illustrating the assist pattern generation method 1. Those elements of the generation method not described below may be substantially the same as the above. More specifically, FIGS. 3A to 3E are diagrams illustrating an example in which the assist pattern generation method 1 is applied to a 2D isolation pattern in a cell edge region UBE.

Referring to FIG. 3A, a semiconductor device 100 may include a cell region CELR and a peripheral circuit region PPCR surrounding the cell region CELR in a plan view. The cell region CELR may include a cell center region UBC and a cell edge region UBE surrounding the cell center region UBC in a plan view. The cell center region UBC and the cell edge region UBE may also be referred to as a unit block center region and a unit block edge region, respectively.

The peripheral circuit region PPCR may include an interface region INF surrounding the cell region CELR and a core region COR surrounding the interface region INF in a plan view. A peripheral circuit PCI may be arranged in the core region COR.

The semiconductor device 100 may include a memory element. Accordingly, the cell region CELR described above may include a memory cell region. The memory device may include, for example, volatile memory devices, such as dynamic random-access memory (DRAM) and static random-access memory (SRAM), or non-volatile memory devices, such as phase-change random-access memory (PRAM), magnetoresistive random-access memory (MRAM), ferroelectric random-access memory (FeRAM), and resistive random-access memory (RRAM). However, the semiconductor devices to which the present disclosure may be applied are not limited to the memory devices. That is, the methods described herein may also be applied to other devices, for example, logic devices.

Although a 2D cell edge region UBE of a memory device is described herein, the scope of this disclosure is not limited thereto. That is, the methods described herein may be applied to patterns including 2D isolation patterns in the manufacturing of other semiconductor devices.

As shown in FIG. 3A, a second region B may be selected in the cell edge region UBE. The left diagram in FIG. 3A shows an actual pattern of a semiconductor device, and the right diagram shows a simplified mask pattern for manufacturing the semiconductor device.

The second region B may be divided into a first selective region B1, a second selective region B2, and a third selective region B3, and then selected. The third selective region B3 may represent an outer region in which regular patterns are continuously arranged, the first selective region B1 may represent a region adjacent to one side of the third selective region B3, and the second selective region B2 may represent a region that is different from the first selective region B1 and adjacent to another side of the third selective region B3. The first selective region B1 and the second selective region B2 may each represent a region that is adjacent to the third selective region B3 and has irregular patterns or no separate patterns.

The first selective region B1 and the second selective region B2 may represent the 2D isolation pattern. The 2D isolation pattern may include an area-type empty space, a large quadrangle, a corner, or the like, which has few patterns adjacent thereto or is far away from adjacent patterns in both directions in the outer peripheral portion of the pattern used as a reference in a plan view.

Referring to FIG. 3B, the intensity maps of the first selective region B1, the second selective region B2, and the third selective region B3 may be individually calculated. The intensity map of each of the first selective region B1, the second selective region B2, and the third selective region B3 may be calculated without separately inserting assist patterns therein. Also, the intensity map of each of the first selective region B1, the second selective region B2, and the third selective region B3 may be calculated without separately inserting the assist pattern in the outer part of the isolation pattern region and the cell region. The intensity map may be calculated by the rigorous simulation described above.

A first intensity map IMB1, a second intensity map IMB2, and a third intensity map IMB3 may correspond to the intensity maps of the first selective region B1, the second selective region B2, and the third selective region B3, respectively. For ease of description, the shapes of the selective regions, intensity maps, and intensity functions described herein may have some differences or inconsistencies in terms of numerical values, regions, etc., and should be understood as conceptual rather than exact. Those skilled in the art will be able to fully understand the intended ideas throughout this conceptual illustration.

Referring to FIG. 3C, a fifth graph G5 shows a first intensity function I_{b1} (x,y) of the first selective region B1 in three dimensions and a sixth graph G6 shows a first intensity function I_{b1} (x,y) of the first selective region B1 in two dimensions. The first intensity function I_{b1} (x,y) may be calculated after noise filtering is performed on the first intensity map IMB1 described above. The noise filtering may be performed, for example, by polynomial regression fitting.

The local extrema and the inflection points may be calculated for the first intensity function I_{b1} (x,y). For example, the first intensity function may have local minima at approximately 8 and 60 on the x-axis. For example, the locations of local minima and inflection points, other than the local maxima, among the local extrema and the inflection points computed by

$$\frac{{dI}_{b 1} ( x , y )}{d x d y} = 0$$

may be selected as the locations at which the assist patterns are inserted. For example, as shown in the sixth graph G6, the local minima are calculated at around x-axis values of 8 and 60, and thus, the assist patterns may be generated at those locations. The size of the assist pattern generated may be the same as described above.

Referring to FIG. 3D, a seventh graph G7 shows a second intensity function I_{b2} (x,y) of the second selective region B2 in three dimensions and an eighth graph G8 shows a second intensity function I_{b2} (x,y) of the second selective region B2 in two dimensions. The second intensity function I_{b2} (x,y) may be calculated after noise filtering is performed on the second intensity map IMB2 described above.

The local extrema and the inflection points may be calculated for the second intensity function I_{b2} (x,y). For example, the second intensity function may have local minima at around 5, 20, 44, and 52 on the x-axis. For example, the locations of local minima and inflection points, other than the local maxima, among the local extrema and the inflection points computed by

$$\frac{{dI}_{b 2} ( x , y )}{d x d y} = 0$$

may be selected as the locations at which the assist patterns are inserted. For example, as shown in the eighth graph G8, the local minima are calculated at the locations corresponding to the x-axis values of approximately 5, 44, and 52, and an inflection point is calculated at the location corresponding to the x-axis value of approximately 20, and thus, the assist patterns may be generated at those locations. The size of the assist pattern generated may be the same as described above. The assist patterns are inserted, and the intensity function may then be recalculated.

Referring to FIG. 3E, a ninth graph G9 shows a recalculated fifth intensity function C5 of the first selective region B1, and a tenth graph G10 shows a sixth intensity function C6 recalculated after the size of the assist pattern of the first selective region B1 is adjusted. However, for ease of description, the shapes of graphs may be different from those of the first intensity function I_{b1} (x,y) described above for the first selective region B1.

In the ninth graph G9, for the intensity map recalculated after the assist patterns are respectively inserted at the locations of four local minima, the analysis region is selected linearly based on the x-axis direction, the fifth intensity function C5 is calculated, and the fifth intensity function C5 is shown based on the x direction. For example, in the ninth graph G9, after the assist patterns are inserted for the first intensity function I_{b1} (x,y) described with reference to FIG. 3C, the intensity map is recalculated, and a portion of the recalculated intensity function is shown on a plane with respect to the x-axis.

The local minimum of the fifth intensity function C5 is observed at each of xₘ₁, xₘ₂, xₘ₃, and xₘ₄. For the four local minima, the sizes of the assist patterns may be adjusted so that the difference between the local minima is less than the first reference value. Here, when calculating the differences between local minima, the differences between at least some of the local minima in the selective region may be calculated, or the differences between adjacent local minima may be calculated.

For example, operation S160 of determining whether the difference between the local minima of the intensity functions is within the first reference value may be performed such that one local minimum among I_{g} (xₘ₁), I_{g} (xₘ₂), I_{g} (xₘ₃), and I_{g} (xₘ₄) is compared to the remaining three, and the difference therebetween is less than or equal to the first reference value. Also, operation S160 of determining whether the difference between the local minima of the intensity functions is within the first reference value may be performed such that the difference between I_{g} (xₘ₁) and I_{g} (xₘ₂), the difference between I_{g} (xₘ₂) and I_{g} (xₘ₃), and the difference between I_{g} (xₘ₃) and I_{g} (xₘ₄) are equal to or less than the first reference value.

Also, the difference between local minima having similar values within a certain range among a plurality of local minima may be calculated to determine whether the difference therebetween is less than or equal to the first reference value. For example, the difference may be calculated between similar local minima within a certain range among the values of I_{g} (xₘ₁), I_{g} (xₘ₂), I_{g} (xₘ₃), and I_{g} (xₘ₄). The difference between I_{g} (xₘ₁) and I_{g} (xₘ₂) and the difference between I_{g} (xₘ₃) and I_{g} (xₘ₄) are each calculated, and it may be determined whether the difference therebetween is less than or equal to the first reference value. For example, the assist pattern may be adjusted to increase in size so that the intensity of the local minima increases, or the assist pattern may be adjusted to decrease in size so that the intensity of the local minima decreases.

As shown in the tenth graph G10, the size of the assist pattern of the first selective region B1 is adjusted by the processes described above, and then, the sixth intensity function C6 is computed by recalculation. Unlike the fifth intensity function C5, the sixth intensity function C6 shows smaller differences between local minima, and the waveform of the sixth intensity function C6 appearing between local minima rises more gently. More specifically, it can be seen that the local maxima of the sixth intensity function C6 appearing between the local minima rise gently with increasing values on the x-axis. In addition, a process of identifying whether the difference between each of the local minima and the residue threshold is greater than the second reference value may be performed.

Through the assist pattern generation method 1, the size of the assist pattern may be adjusted by iteratively performing rigorous simulation for the intensity value. As described above, when the waveform of intensities becomes gentle and the deviation between local minima decreases, even if deviation of focus or variation in illuminance occurs in the actual process, the change in exposure intensity at each location may be relatively uniform. This is particularly important in microfabrication processes in which the DoF is limited, and the margin range of the DoF may be further secured.

For example, the local minima of the intensity function may be reduced at or above the residue threshold by inserting the assist pattern. With respect to the actual pattern formed on the wafer by the block pattern, optical effects, such as interference and diffraction, may be exerted on the block pattern by arranging the assist pattern adjacent to the block pattern. For example, when the assist pattern is formed at an optimized size within a range in which the assist pattern is not formed as residue, the DoF margin of the main pattern to be actually formed may be secured.

Therefore, in the assist pattern generation method 1, even if there is a deviation of focus or a change in exposure conditions, the main pattern may be formed more stably by the optimized assist pattern, and thus, the process margin may expand. Therefore, the yield of semiconductor devices manufactured may be improved.

Referring to FIG. 3F, by performing the assist pattern generation method 1, assist patterns may be added to the mask pattern of FIG. 3A as shown in FIG. 3F. First assist patterns B1_AP1 may not be uniformly spaced apart from each other, and the widths of individual line assist patterns may be at least partially different from each other. The first assist patterns B1_AP1 may represent optimized assist patterns that are generated in the first selective region B1 by the assist pattern generation method 1 described above. For example, the first assist patterns B1_AP1 may include a sub resolution assist feature (SRAF).

For example, the first assist patterns B1_AP1 may include four line assist patterns, and two of the line assist patterns provided in the center of the first assist patterns B1_AP1 may have widths greater than those of the remaining line assist patterns. The widths of the two line assist patterns provided in the center of the first assist patterns B1_AP1 may be different from each other.

The assist patterns may be generated at locations at which the local minima and the inflection points occur, the difference between the values at the local minima and the inflection points may be calculated based on the first reference value, and the size of the assist patterns may be adjusted. Therefore, the sizes of the assist patterns may be at least partially different from each other. Also, since the assist patterns are arranged at locations at which the local minima and the inflection points occur, the intervals between the assist patterns may not be uniform.

Second assist patterns B3_AP2 and third assist patterns B3_AP3 may represent optimized assist patterns that are generated in the third selective region B3 by the assist pattern generation method 1 described above. For example, the second assist patterns B3_AP2 and the third assist patterns B3_AP3 may include an anti-SRAF. The second assist patterns B3_AP2 and the third assist patterns B3_AP3 may be formed, in the outer peripheral portions of the cell regions, at locations of the outer peripheral portions of the regularly formed main patterns. The DoF margin may be further secured in the adjacent patterns of the cell region by arranging the second assist patterns B3_AP2 and the third assist patterns B3_AP3 corresponding to the anti-SRAF.

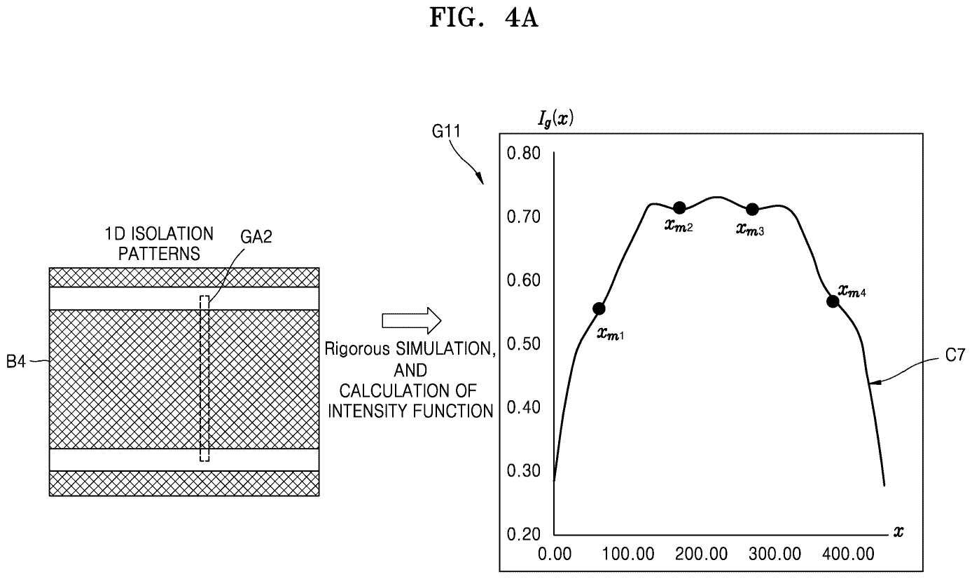

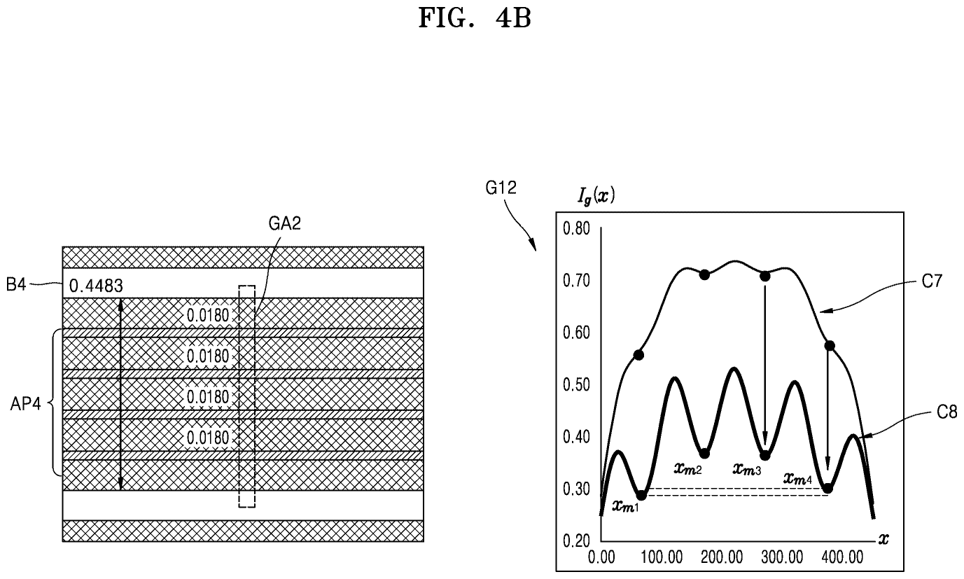

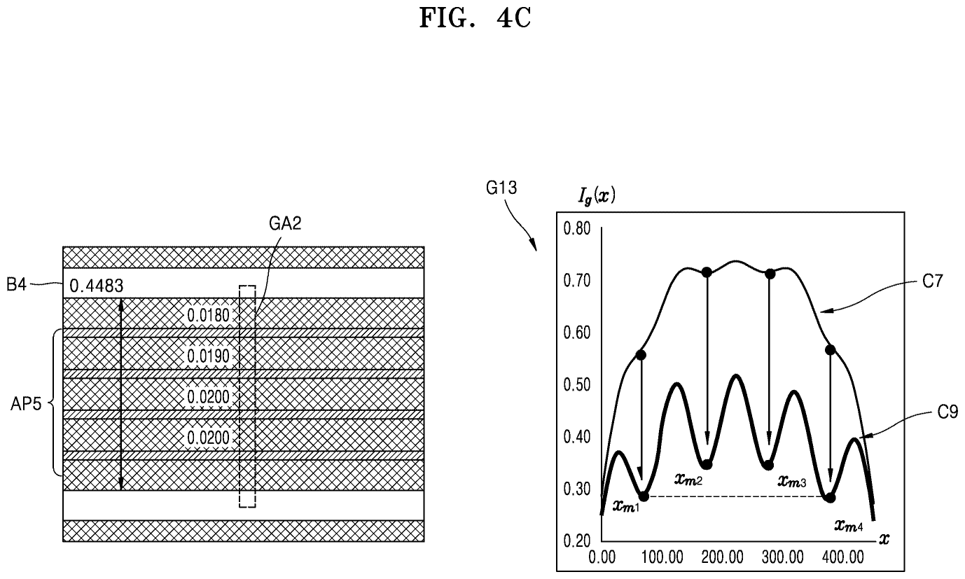

FIGS. 4A to 4C are diagrams illustrating the assist pattern generation method 1. More specifically, FIGS. 4A to 4C are diagrams illustrating an example in which the assist pattern generation method 1 is applied to a 1D isolation pattern. Those elements of the assist pattern generation method 1 not described below may be substantially the same as the above.

Referring to FIG. 4A, a fourth selective region B4 may be selected, and a first analysis region GA2 for computing an intensity function in the fourth selective region B4 may be selected. The intensity map undergoes the rigorous simulation, and a seventh intensity function C7 for the first analysis region GA2 may be calculated and shown in an eleventh graph G11. For example, in the seventh intensity function C7, a total of four local minima and inflection points may be calculated in the first analysis region GA2.

Referring to FIG. 4B, a fourth assist pattern AP4 having a uniform width and size may be generated at each of the four locations xₘ₁, xₘ₂, xₘ₃, and xₘ₄ described above with reference to FIG. 4A and then inserted into the mask, and an eighth intensity function C8 obtained by recalculating the intensity function may be shown in a twelfth graph G12. The fourth assist pattern AP4 may include an anti-SRAF.

The fourth assist pattern AP4 may be generated at the location of each of the local minima and inflection points, and the magnitudes of the new local minima of the eighth intensity function C8, which is a changed intensity function, may be compared to each other. It may be determined whether the difference between the local minima is within the range of the first reference value.

The difference between local minima in similar ranges of values may be compared to the first reference value. For example, since the values of I_{g} (xₘ₁) and I_{g} (xₘ₄) are similar, the size of the fourth assist pattern AP4 may be adjusted by reducing the difference between the two values so that the difference therebetween is within the range of the first reference value. For example, the difference between the intensity value at xₘ₁ and the intensity value at xₘ₄ may be reduced by reducing the width of the assist pattern located at xₘ₁ or increasing the width of the assist pattern located at xₘ₄. Also, the difference between the intensity value at xₘ₁ and the intensity value at xₘ₄ may be reduced by decreasing the width of the assist pattern located at xml and simultaneously increasing the width of the assist pattern located at xₘ₄.

Referring to FIG. 4C, a fifth assist pattern AP5 having a size adjusted from the fourth assist pattern AP4 is generated at the four locations xₘ₁, xₘ₂, xₘ₃, and xₘ₄ described above with reference to FIG. 4B and then inserted into the mask, a ninth intensity function C9 obtained by recalculating the intensity function may be shown in a thirteenth graph G13. For example, unlike fourth assist patterns AP4, fifth assist patterns AP5 may have widths that are at least partially different from each other.

For example, the width of the assist pattern located lowermost among the fifth assist patterns AP5 may increase to 0.020 from 0.018 of the fourth assist patterns AP4. That is, the difference between the intensity values of xₘ₁ and xₘ₄ may be reduced by increasing the width of the assist pattern located at xₘ₄. Based on the same principle as described above, the difference in intensity values in xₘ₂ and xₘ₃ may also be reduced by adjusting the size of the assist pattern. A process of determining the residue threshold for the local minima of each of the eighth intensity function C8 and the ninth intensity function C9 may be performed as described above.

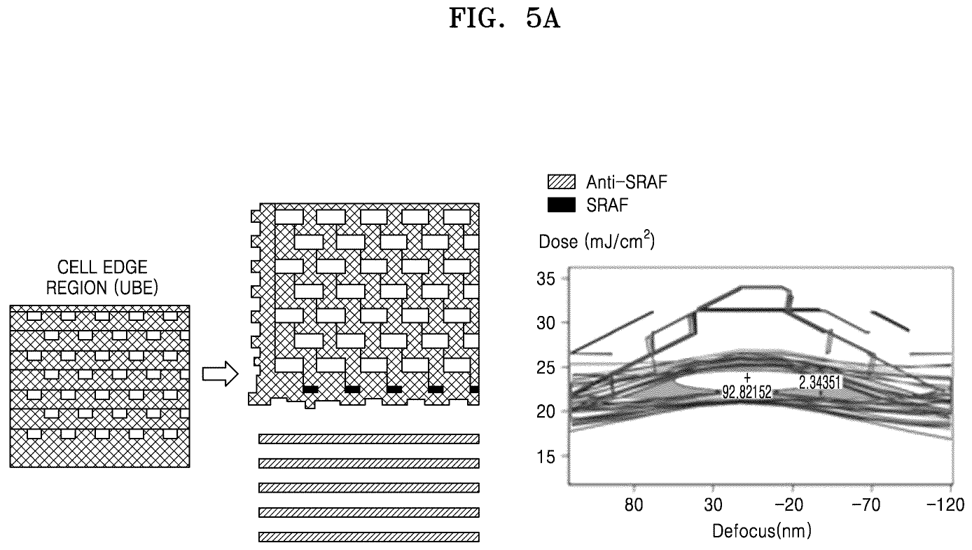

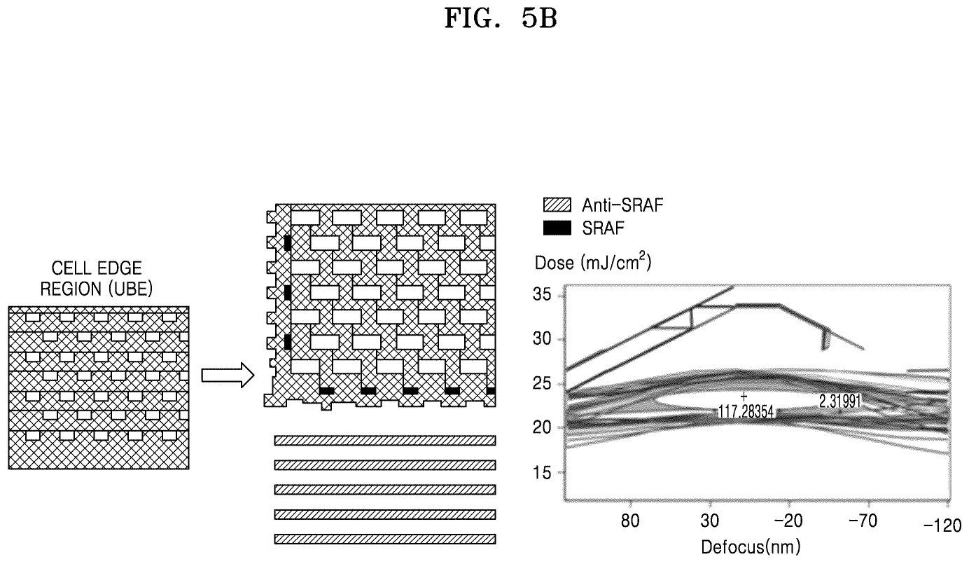

The fourth assist pattern AP4 and the fifth assist pattern AP5 may include, for example, a blocking assist pattern that blocks light. For example, the fourth assist pattern AP4 and the fifth assist pattern AP5 described with reference to FIGS. 4A and 4B may represent the anti-SRAF and, at the same time, the blocking assist patterns. In some implementations, the assist pattern may include a transmissive assist pattern that transmits light. The assist pattern corresponding to the SRAF among the assist patterns described below with reference to FIG. 5A and FIG. 5B may include a transmissive assist pattern. As used herein, the blocking assist pattern may represent the assist pattern for blocking light, and the transmissive assist pattern may represent the assist pattern for transmitting light.

FIG. 5A is a diagram showing a mask including assist patterns formed by general rules. FIG. 5B is a diagram showing a mask including assist patterns generated by the assist pattern generation method 1. More specifically, FIG. 5A is a diagram showing assist patterns formed by the general rules for 2D isolation patterns in a cell edge region UBE, and FIG. 5B is a diagram illustrating an example of applying the assist pattern generation method 1 to the 2D isolation patterns in a cell edge region UBE.

Referring to FIG. 5A, the assist patterns formed by the general rules may be arranged at uniform intervals with uniform widths, such as the SRAF patterns formed linearly. In addition, the assist patterns described above may be arranged inside block patterns in the cell edge region, as in the anti-SRAF patterns.

Referring to FIG. 5B, in the optimized assist patterns formed by the assist pattern generation method 1, for example, the intervals between the linearly formed SRAF patterns may be at least partially different from each other, and the widths of the SRAF patterns may be at least partially different from each other. In addition, unlike the assist patterns formed by the general rules, additional anti-SRAF patterns may be generated in an isolation pattern region within a block pattern region. Also, the sizes of the optimized anti-SRAF patterns formed by the assist pattern generation method 1 may be different from the sizes of the anti-SRAF patterns formed by the general rules. This is because the sizes and locations of the assist patterns are adjusted repeatedly by the rigorous simulation described above for the selective region, thereby forming the optimized assist patterns.

The assist patterns formed by the general rules are difficult to optimize to provide optimized assist patterns for irregular patterns in cell edge regions, isolation patterns, and isolation spaces. However, the assist patterns optimized by the assist pattern generation method 1 may be formed by adjusting the sizes of the assist patterns on the basis of intensity values obtained by the rigorous simulation repeated a plurality of times, thereby generating the assist patterns that are more optimized in the cell edge regions, isolation patterns, and isolation spaces.

In the graph of FIG. 5A showing computation of DoF for assist patterns formed by the general rules, the computed range of DoF is 92.8 nm. In the graph of FIG. 5B showing computation of DoF for the optimized assist patterns formed by the assist pattern generation method 1, the computed range of DoF is 117.3 nm, representing an improvement.

Therefore, a wide range of DoF may be secured by the optimized assist pattern generated by the assist pattern generation method 1. When a process is performed based on regions in which regular patterns, such as cell regions, are densely packed, the possibility of occurrence of pattern defects, such as bridging, necking, and line breaking, which are relatively likely to occur in regions, such as the cell edge region, the isolation pattern, and the isolation space, may be reduced.

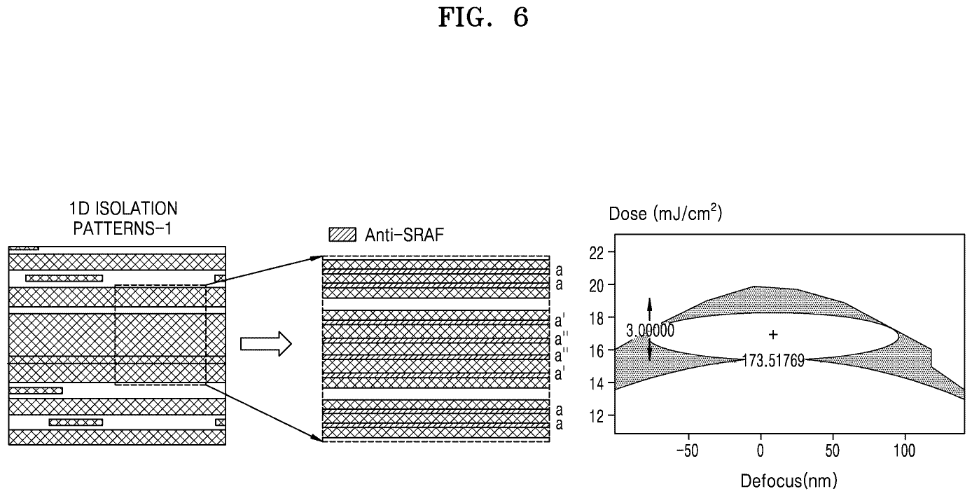

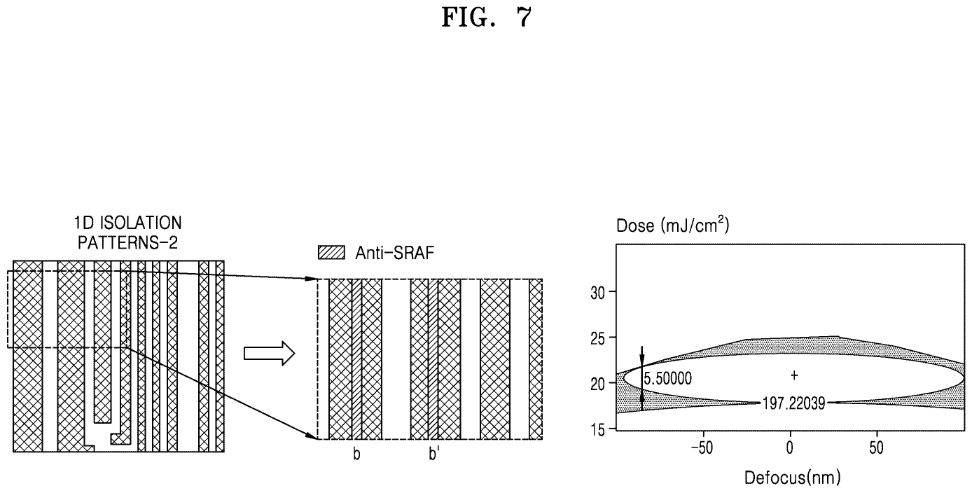

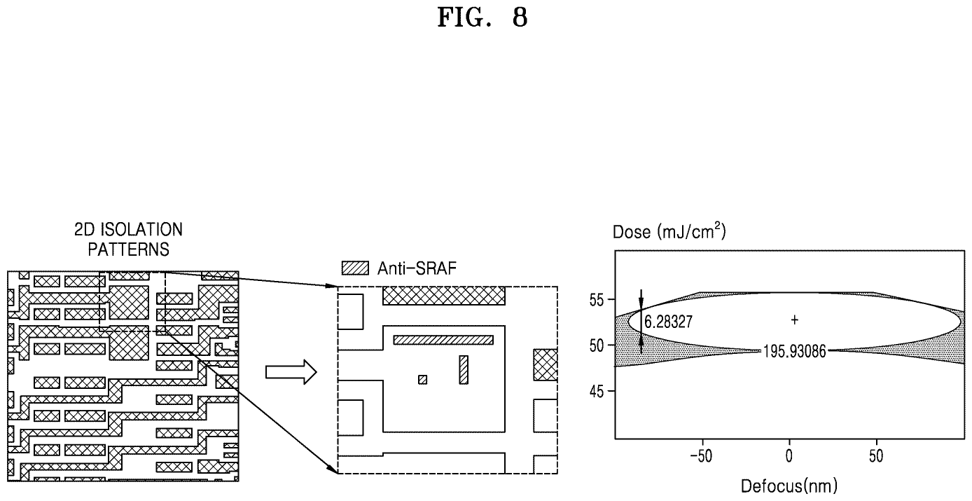

FIGS. 6 to 8 are diagrams showing examples of masks including assist patterns generated and optimized by the assist pattern generation method 1. More specifically, FIGS. 6 and 7 show masks, including assist patterns generated and optimized by the assist pattern generation method 1 for different 1D isolation patterns, and graphs of DoF thereof. Also, FIG. 8 shows masks, including assist patterns generated and optimized by the assist pattern generation method 1 for a 2D isolation pattern, and a graph of DoF thereof.

Referring to FIG. 6, assist patterns generated by the assist pattern generation method 1 may be provided on a mask that does not include assist patterns of the 1D isolation pattern on the left. The assist patterns may have a line assist pattern shape, but at least some of the line assist patterns may have different widths. For example, the assist patterns may be optimized so that the assist patterns at the top and bottom have a width of a, and the assist patterns at the center have a width of a′ or a″. That is, the width may vary depending on the locations of the assist patterns, or the intervals between the assist patterns may not be constant.

The assist patterns formed by the general rules may not generate assist patterns in the 1D isolation patterns. When no assist pattern is generated as described above, the range of DoF is 135.1 nm when the DoF is computed based on relatively bright block patterns located on both sides of the transmissive patterns. On the other hand, as shown in FIG. 6, when the optimized assist patterns generated by the assist pattern generation method 1 are arranged, the range of DoF is computed as 173.5 nm when the DoF is computed. That is, the range of DoF may be further secured or increased by the assist patterns optimized by the assist pattern generation method 1.

As the range of DoF is secured, the process margin may be widened, and the time required to optimize the overlay and focus values during setting of the exposure process equipment may be reduced. In addition, since the repetitions of complicated OPC may be reduced, the assist pattern generation method 1 may improve the productivity of semiconductor manufacturing.

Referring to FIG. 7, assist patterns generated by the assist pattern generation method 1 may be provided on a mask that does not include assist patterns of the 1D isolation pattern on the left. The assist patterns may have a linear assist pattern shape, but at least some of the line assist patterns may have different widths. For example, the assist patterns may be optimized so that the left and center assist patterns have widths b and b′, respectively. Also, the locations of the two line assist patterns relative to the transmissive patterns may not be determined collectively. For example, rather than line assist patterns being located only at the centers of transmissive patterns, assist patterns may be generated at locations at which local minima and inflection points of intensities appear, as described above.

The assist patterns formed by the general rules may not generate assist patterns in the 1D isolation patterns. When no assist pattern is generated, the range of DoF is 170.9 nm when the DoF is computed based on relatively bright block patterns located on both sides of the transmissive patterns. On the other hand, as shown in FIG. 7, when the optimized assist patterns generated by the assist pattern generation method 1 are arranged, the range of DoF is computed as 197.2 nm when the DoF is computed as described above.

Referring to FIG. 8, assist patterns generated by the assist pattern generation method 1 may be provided on a mask that does not include assist patterns of the 2D isolation pattern on the left. The assist patterns may include line assist patterns and dot-shaped assist patterns. A relatively long line assist pattern, a relatively short line assist pattern perpendicular to and spaced laterally apart from the relatively long line assist pattern, and a dot-shaped assist pattern spaced apart from each of the two line assist patterns may be generated by the assist pattern generation method 1. As described above, the assist patterns may be generated at the locations at which the local minima and the inflection points appear in the intensity map computed by the rigorous simulation of the 2D isolation patterns.

The assist patterns formed by the general rules may not generate assist patterns in the 2D isolation patterns. When no assist pattern is generated, the range of DoF is 141.5 nm when the DoF is computed based on relatively bright block patterns located on both sides of the transmissive patterns. On the other hand, as shown in FIG. 8, when the optimized assist patterns generated by the assist pattern generation method 1 are arranged, the range of DoF is computed as 195.9 nm when the DoF is computed as described above.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination. Operations in the drawings may be performed in a different order to that illustrated.

While certain examples have been particularly shown and described, it will be understood that various changes in form and details may be made therein without departing from the spirit and scope of this disclosure.

What is claimed is:

1. An assist pattern generation method for lithographic masks, the method comprising:
selecting a selective region in a mask pattern;
calculating an intensity map in the selective region, wherein the intensity map represents an intensity of light transmitted through the mask pattern;
based on the intensity map, calculating an intensity function of an analysis region in the selective region;
based on the intensity function, selecting locations of assist patterns;
generating the assist patterns at the selected locations;
recalculating the intensity function of the analysis region based on the assist patterns;
determining whether a difference between a first value of the intensity function and a second value of the intensity function satisfies a first threshold condition;
determining whether a second threshold condition based on the intensity function and a residue threshold is satisfied; and
determining final assist patterns based on whether the first threshold condition and the second threshold condition are satisfied.

2. The assist pattern generation method of claim 1, wherein calculating the intensity map in the selective region comprises performing a physics-based simulation, and
wherein the physics-based simulation comprises analyzing fine patterns based on Maxwell's equations.

3. The assist pattern generation method of claim 1, wherein the first value and the second value comprise at least one of local minima or inflection points of the intensity function,
wherein determining whether the difference between the first value and the second value satisfies the first threshold condition comprises determining that the difference is greater than a first reference value, and
wherein determining the final assist patterns comprises:
based on the difference between the first value and the second value being greater than the first reference value, adjusting a size of at least one of the assist patterns.

4. The assist pattern generation method of claim 1, wherein the selective region comprises a cell edge region that includes an isolation pattern.

5. The assist pattern generation method of claim 1, wherein selecting the selective region is based on at least one of a degree of isolation of the selective region or a spacing of the selective region from repetitive patterns of the mask.

6. The assist pattern generation method of claim 1, wherein the selected locations comprise at least one of local maxima, local minima, or inflection points of the intensity function.

7. The assist pattern generation method of claim 1,
wherein determining whether the difference between the first value and the second value satisfies the first threshold condition comprises determining that the difference is greater than a first reference value, and
wherein determining the final assist patterns comprises:
based on the difference between the first value and the second value being greater than the first reference value, adjusting a size of at least one of the assist patterns.

8. The assist pattern generation method of claim 1,
wherein determining whether the second threshold condition based on the intensity function and the residue threshold is satisfied comprises determining whether a local minimum of the intensity function is greater than the residue threshold, and
wherein determining the final assist patterns comprises:
based on the local minimum of the intensity function not being greater than the residue threshold, adjusting a size of at least one of the assist patterns.

9. The assist pattern generation method of claim 1, wherein the first value and the second value correspond to adjacent locations among locations corresponding to local minima and inflection points of the intensity function.

10. The assist pattern generation method of claim 1, wherein calculating the intensity function comprises performing noise filtering on the intensity map.

11. The assist pattern generation method of claim 10, wherein the noise filtering comprises polynomial regression fitting.

12. The assist pattern generation method of claim 1, wherein the mask comprises patterns and spaces in the selective region, the patterns and spaces providing a wiring pattern, and
wherein the assist patterns comprise a sub resolution assist feature (SRAF) and an anti-SRAF.

13. The assist pattern generation method of claim 1, wherein the analysis region has a line shape.

14. The assist pattern generation method of claim 1, wherein the assist patterns, as initially generated, have a smallest size that satisfies a mask rule check.

15. An assist pattern generation method for lithographic masks, the method comprising:
selecting a selective region in a mask pattern;
calculating an intensity map in the selective region, wherein the intensity map represents an intensity of light transmitted through the mask pattern;
based on the intensity map, calculating an intensity function of an analysis region in the selective region;
based on the intensity function, selecting locations of assist patterns;
generating the assist patterns at the selected locations;
recalculating the intensity function of the analysis region based on the assist patterns;
determining that a first difference between a first value of the intensity function and a second value of the intensity function is greater than a first reference value, wherein the first value and the second value comprise values of at least one of local minima or inflection points of the intensity function;
based on determining that the first difference is greater than the first reference value, performing a first adjustment to a size of at least one of the assist patterns;
determining that a second difference between a local minimum of the intensity function and a residue threshold is less than a second reference value;
based on determining that the second difference is less than the second reference value, performing a second adjustment to a size of at least one of the assist patterns; and
generating final assist patterns based on the first adjustment and the second adjustment.

16. The assist pattern generation method of claim 15, wherein performing the first adjustment comprises adjusting the size of at least one of the assist patterns such that the first difference is less than the first reference value, and
wherein performing the second adjustment comprises decreasing a size of a transmissive assist pattern among the assist patterns or increasing a size of a block assist pattern among the assist patterns.

17. The assist pattern generation method of claim 15, wherein a range of depth of focus of the selective region comprising the final assist patterns is greater than a range of depth of focus of the selective region comprising the assist patterns prior to the first adjustment and the second adjustment.

18. The assist pattern generation method of claim 15, wherein the final assist patterns comprise a plurality of line assist patterns,
wherein widths of at least some of the plurality of line assist patterns are different from one another, and
wherein intervals between at least some of the plurality of line assist patterns are different from one another.

19. An assist pattern generation method for lithographic masks, the method comprising:
selecting a selective region in a mask pattern;
calculating an intensity map in the selective region, wherein the intensity map represents an intensity of light transmitted through the mask pattern, wherein calculating the intensity map comprises performing a physics-based simulation, and wherein the physics-based simulation comprises analyzing fine patterns based on Maxwell's equations;
calculating an intensity function of an analysis region in the selective region, wherein calculating the intensity function comprises performing noise filtering on the intensity map;
selecting locations of assist patterns based on the intensity function;
generating the assist patterns at the selected locations;
recalculating the intensity function of the analysis region based on the assist patterns;
determining that a first difference between a first value of the intensity function and a second value of the intensity function is greater than a first reference value, wherein the first value and the second value comprise values of at least one of local minima or inflection points of the intensity function;
based on determining that the first difference is greater than the first reference value, performing a first adjustment to a size of at least one of the assist patterns, wherein the first adjustment causes the first difference to be less than the first reference value;
determining that a second difference between a local minimum of the intensity function and a residue threshold is less than a second reference value;
based on determining that the second difference is less than the second reference value, performing a second adjustment to a size of at least one of the assist patterns, wherein the second adjustment comprises decreasing a size of a transmissive assist pattern among the assist patterns decreases or increasing a size of a block assist pattern among the assist patterns;
generating final assist patterns based on the first adjustment and the second adjustment; and
manufacturing a lithographic mask comprising the final assist patterns,
wherein a range of depth of focus of the selective region comprising the final assist patterns is greater than a range of depth of focus of the selective region comprising the assist patterns prior to the first adjustment and the second adjustment.

20. The assist pattern generation method of claim 19, wherein the selective region comprises at least one of a cell edge region, a one-dimensional isolation pattern, or a two-dimensional isolation pattern,
wherein the final assist patterns comprise a plurality of line assist patterns,
wherein widths of at least some of the plurality of line assist patterns are different from one another,
wherein intervals between at least some of the plurality of line assist patterns are different from one another,
wherein the noise filtering comprises polynomial regression fitting, and
wherein the assist patterns, as initially generated, have a smallest size that satisfies a mask rule check.
